(19) United States
(12) Patent Application Publication
(10) Pub. No.: US 2009/0212355 A1
(43) Pub. Date: Aug. 27, 2009

(54) Metal-Oxide-Semiconductor Transistor Device and Method for Making the Same

(76) Inventor: Hsiu-Wen Hsu, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 12/127,799

(22) Filed: May 27, 2008

(30) Foreign Application Priority Data
Feb. 21, 2008 (TW) 097106097

(51) Int. Cl. H01L 29/00; H01L 21/336

(52) U.S. Cl. 257/328; 438/269; 257/E29.001; 257/E21.409

(57) ABSTRACT

A metal-oxide-semiconductor transistor device includes a semiconductor substrate, an epitaxial layer formed on the semiconductor substrate, an oxide layer formed on the epitaxial layer, a gate structure formed on the oxide layer, and a shallow junction well formed on the two lateral sides of the gate structure including a source region and a heavy doping region. The gate structure includes a conductive layer having a gap on top of the sidewall of the conductive layer and a spacer formed on the gap.

### BACKGROUND OF THE INVENTION

1. Field of the Invention

The present invention relates to a metal-oxide-semiconductor transistor device and a method for making the same, and more particularly, to a metal-oxide-semiconductor transistor device having low drain-source on-state resistance and a method for making the same.

2. Description of the Prior Art

A power metal-oxide-semiconductor field effect transistor (Power MOSFET) is widely used in power electronic applications, such as a power supply, an industrial instrument, a lamp electronic ballast, an electronic ignition system, a computer motherboard, a battery for a portable electronic device, and a communications equipment. The power MOSFET has many different types of structures and one of these types is a vertical double diffused metal-oxide-semiconductor (VDMOS) transistor.

Please refer to FIG. 1, which illustrates a cross-section diagram of a MOSFET device 10 according to the prior art. The MOSFET device 10 is a VDMOS device, which comprises a semiconductor substrate 100, an epitaxial layer 102, an oxide layer 104, a gate structure 106 and a well region 108. The semiconductor substrate 100 is a silicon substrate and the oxide layer 104 is formed on the epitaxial layer 102 formed on the semiconductor substrate 100, and the related fabrication method is well known in the art and is not given here. The gate structure 106 is formed by a polysilicon layer that is remained after an etching process. An opening is formed on the remaining polysilicon layer after the etching process and the well region 108 is formed after performing an ion implantation process in the opening.

Please refer to FIG. 2 to FIG. 5, which illustrate cross-section diagrams of the MOSFET device 10 in different steps of a fabrication process. FIG. 2 is a cross-section diagram of the MOSFET device 10 after forming the well region 108. FIG. 3 is a cross-section diagram of the MOSFET device 10 after a source implantation process. FIG. 4 is a cross-section diagram of the MOSFET device 10 after a heavy body implantation process. FIG. 5 is a cross-section diagram of the MOSFET device 10 after forming a dielectric layer. In addition, a metal layer (not shown) is formed on the dielectric layer. In a word, the MOSFET device 10 is formed according to many different steps and each step is well known in the art and is not given here.

Please refer to FIG. 6, which illustrates a schematic diagram of channel length of the MOSFET device 10. In FIG. 6, H is channel length, D is the depth of the well region 108, S is the distance between two gate structures, and P is the distance of the dielectric layer of the MOSFET device 10 and P must keep a fixed distance to isolate source metal and gate. Note that, the channel length H is fixed for maintaining the same device characteristic even though the fabrication processes may be different from one MOSFET device to another.

On the other hand, a parasitic Junction field effect transistor (parasitic JFET) the MOSFET device 10 grows when the depth of the well region 108 is getting larger so that a drain-source on-state resistance (Rdson) in the MOSFET device 10 increases. As a result, the efficiency of the MOSFET device 10 is reduced.

### SUMMARY OF THE INVENTION

It is therefore a primary objective of the claimed invention to provide a metal-oxide-semiconductor transistor device and method for making the same.

The present invention discloses a metal-oxide-semiconductor (MOS) transistor device comprising a semiconductor substrate, an epitaxial layer formed on the semiconductor substrate, an oxide layer formed on the epitaxial layer, a gate structure formed on the oxide layer comprising a conductive layer having a gap on the top of the sidewall of the conductive layer and a spacer formed on the gap, and a shallow junction well region formed on the two lateral sides of the gate structure comprising a source region and a heavy body region.

The present invention further discloses a method for fabricating a metal-oxide-semiconductor (MOS) transistor device comprising providing a semiconductor substrate, forming an epitaxial layer on the semiconductor substrate, forming an oxide layer on the epitaxial layer, forming a conductive layer on the oxide layer, forming a first opening on the conductive layer, performing a first ion implantation process on the first opening for forming a shallow junction well region, depositing an oxide layer and performing an etching back process for forming a spacer on the sidewall of the first opening, performing an etching process with the spacer as a mask for forming a gate structure, forming a source region and a heavy body region in the shallow junction well region on the two lateral sides of the gate structure, and performing a depositing process and an etching process for forming a dielectric layer and a metal layer for forming the MOS transistor device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-section diagram of a MOSFET device according to the prior art.

FIG. 2 is a cross-section diagram of the MOSFET device shown in FIG. 1 after forming a well region.

FIG. 3 is a cross-section diagram of the MOSFET device shown in FIG. 1 after a source implantation process.

FIG. 4 is a cross-section diagram of the MOSFET device shown in FIG. 1 after a heavy body implantation process.

FIG. 5 is a cross-section diagram of the MOSFET device shown in FIG. 1 after forming a dielectric layer.

FIG. 6 is a schematic diagram of channel length of the MOSFET device shown in FIG. 1.

FIG. 7 is a cross-section diagram of a MOSFET device according to an embodiment of the present invention.

FIG. 8 is a flowchart of a process for fabricating the MOSFET device shown in FIG. 7.

FIG. 9 to FIG. 14 are cross-section diagrams of the MOSFET device shown in FIG. 7 during each step in the process shown in FIG. 8.

FIG. 15 is a schematic diagram of channel length of the MOSFET device shown in FIG. 7.

FIG. 16 is a flowchart of a process for fabricating a MOSFET device according to an embodiment of the present invention.

FIG. 17 to FIG. 23 are cross-section diagrams of a MOSFET device during each step in the process shown in FIG. 16.

FIG. 24 to FIG. 27 are cross-section diagrams of a MOSFET device during each step in the process according to an embodiment of the present invention.

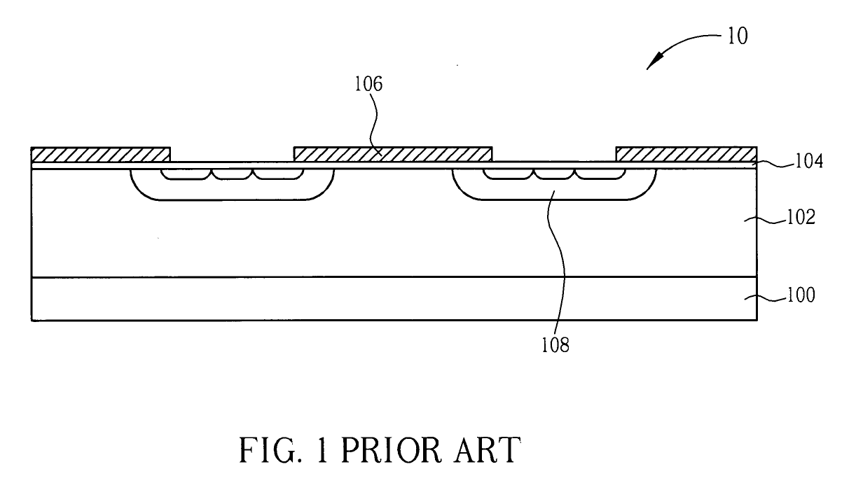

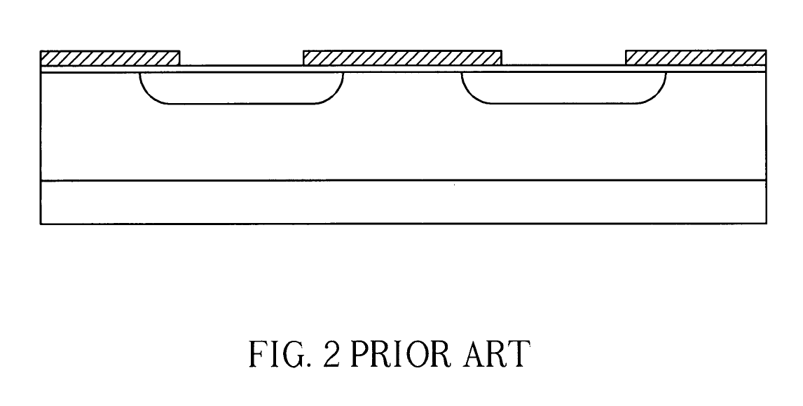

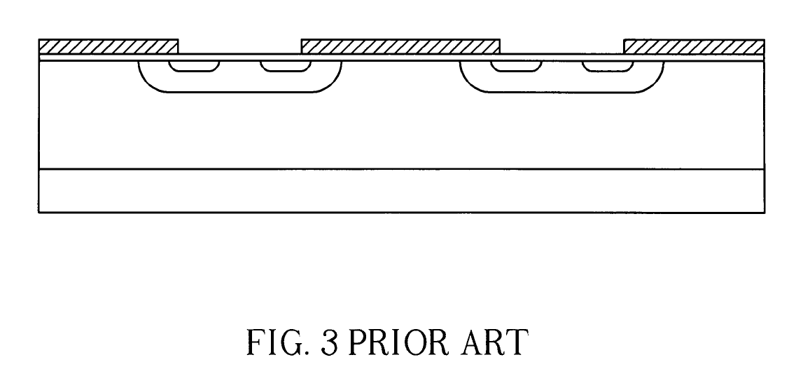

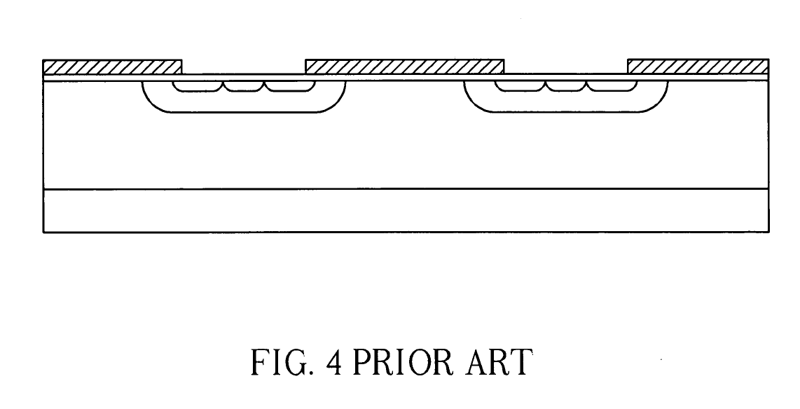

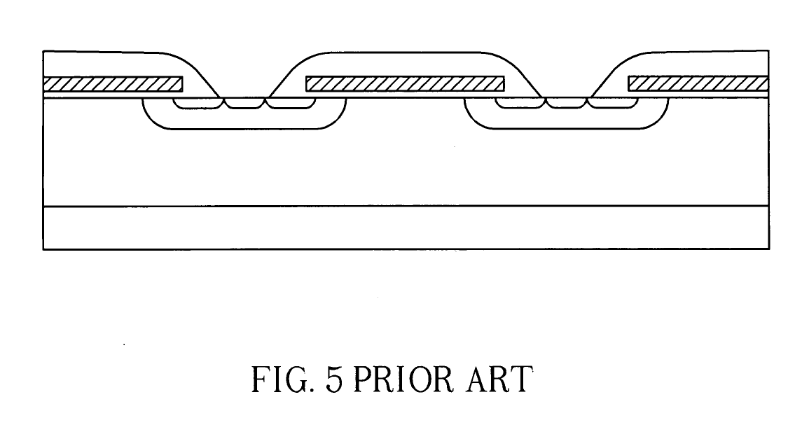

### DETAILED DESCRIPTION

It is known from the prior art that the depth of the well region of a MOSFET device is related to a drain-source on-state resistance (Rdson) in the MOSFET device. The present invention is based on the fact that if the depth of the well region of a MOSFET device is minimized and the channel length of the MOSFET device is fixed at the same time, the MOSFET device shall have a low Rdson.

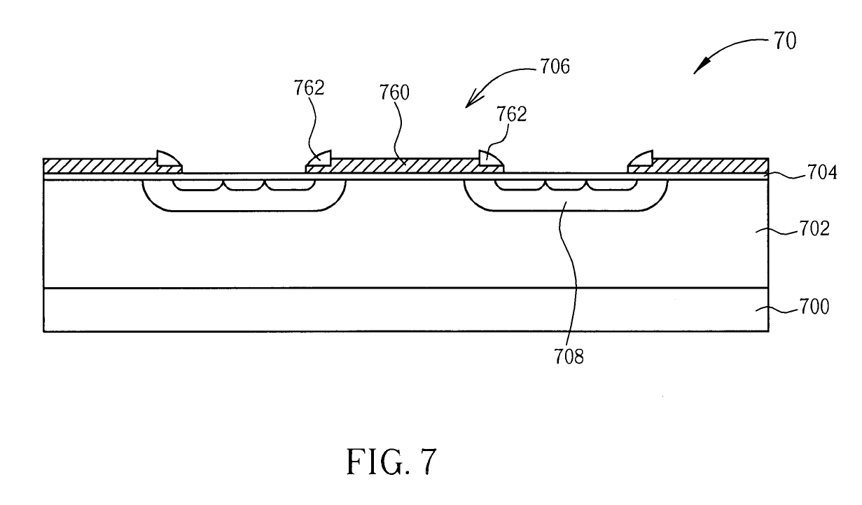

Please refer to FIG. 7, which illustrates a cross-section diagram of a MOSFET device 70 according to an embodiment of the present invention. The MOSFET device 70 is a vertical double diffused metal-oxide-semiconductor (VDMOS) transistor, which comprises a semiconductor substrate 700, an epitaxial layer 702, an oxide layer 704, a gate structure 706 and a well region 708. The semiconductor substrate 700 is a silicon substrate. The oxide layer 704 is formed on the epitaxial layer 702 formed on the semiconductor substrate 700, and related fabrication method is well known in the art and is not given here. The gate structure 706 is formed on the oxide layer 704 and comprises a conductive layer 760 and a spacer 762. As shown in FIG. 7, a gap is on the top of the sidewall of the conductive layer 760 and the gap is covered with the spacer 762. The well region 708 is formed on the two lateral sides of the gate structure 706 and comprises a source region and a heavy body region.

Note that, the conductive layer 760 is formed according to a first etching process and a second etching process. At the beginning, the conductive layer 760 is a polysilicon layer formed on the oxide layer 704. The first etching process is utilized for etching a portion of the polysilicon layer for forming a first opening. The first opening is utilized for performing an ion implantation process for forming the well region 708. Note that, the first etching process only etches a portion of the polysilicon layer so that the etching depth does not reach the top of the oxide layer 704 yet. Next, the spacer 762 is formed according to a deposition process and an etching back process. Furthermore, the second etching process is utilized for etching the remaining polysilicon layer to the top of the oxide layer 704 via the spacer 762 as a mask for forming a second opening. The second opening is utilized for performing an ion implantation process for forming the source region and the heavy body region in the well region 708. In addition, the semiconductor substrate 700 is a silicon substrate. The oxide layer 704 is made of silicon oxide and the conductive layer 760 is made of polysilicon.

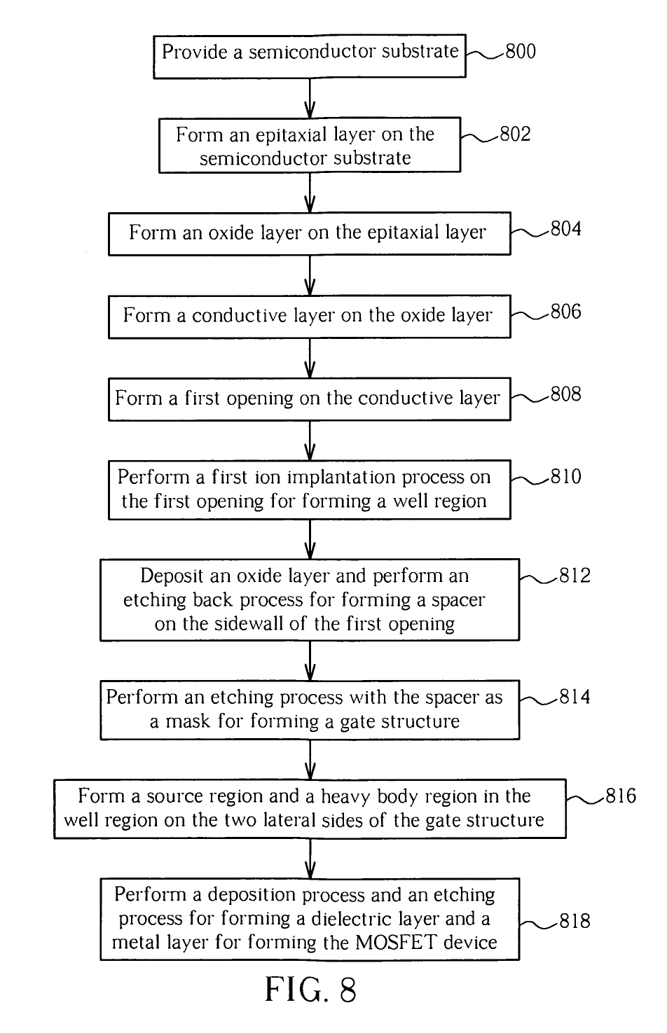

Please refer to FIG. 8. FIG. 8 is a flowchart of a process 80 for fabricating the MOSFET device 70. The process 80 comprises the following steps:

Step 800: Provide a semiconductor substrate.

Step 802: Form an epitaxial layer on the semiconductor substrate.

Step 804: Form an oxide layer on the epitaxial layer.

Step 806: Form a conductive layer on the oxide layer.

Step 808: Form a first opening on the conductive layer.

Step 810: Perform a first ion implantation process on the first opening for forming a well region.

Step 812: Deposit an oxide layer and perform an etching back process for forming a spacer on the sidewall of the first opening.

Step 814: Perform an etching process with the spacer as a mask for forming a gate structure.

Step 816: Form a source region and a heavy body region in the well region on the two lateral sides of the gate structure.

Step 818: Perform a deposition process and an etching process for forming a dielectric layer and a metal layer for forming the MOSFET device.

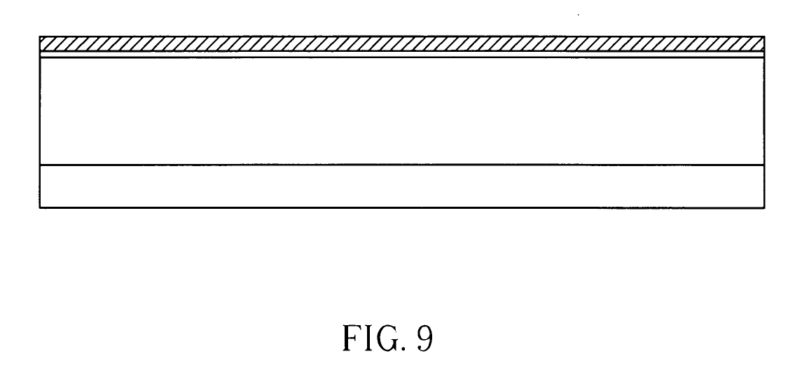

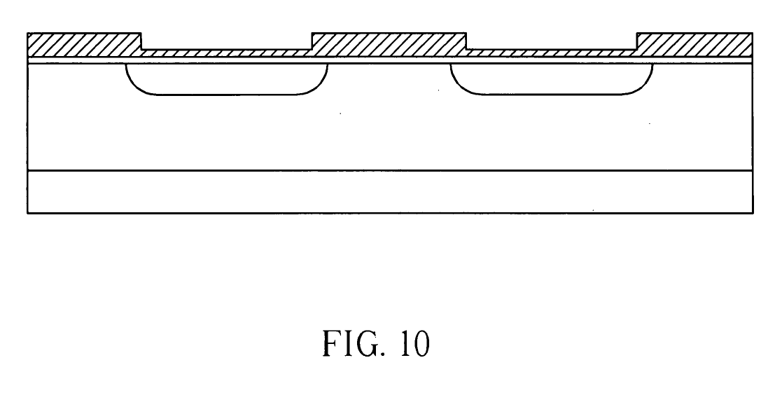

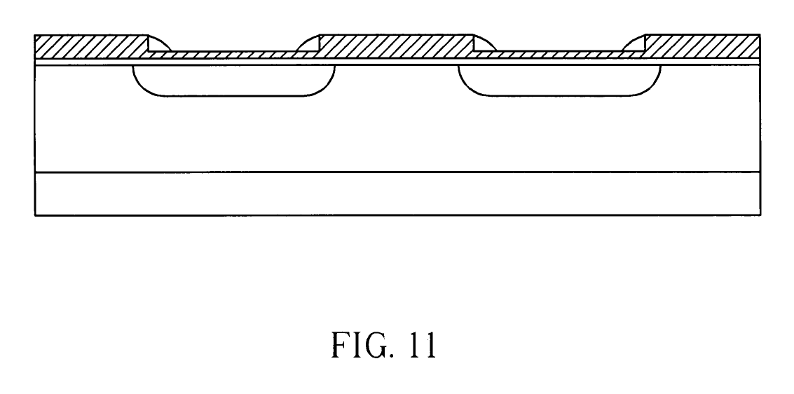

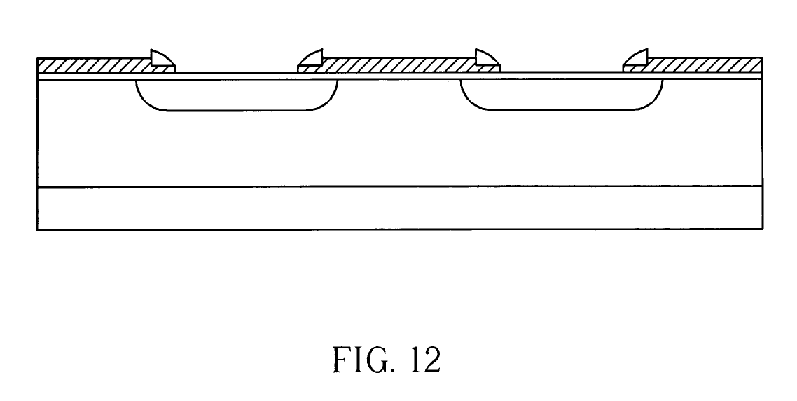

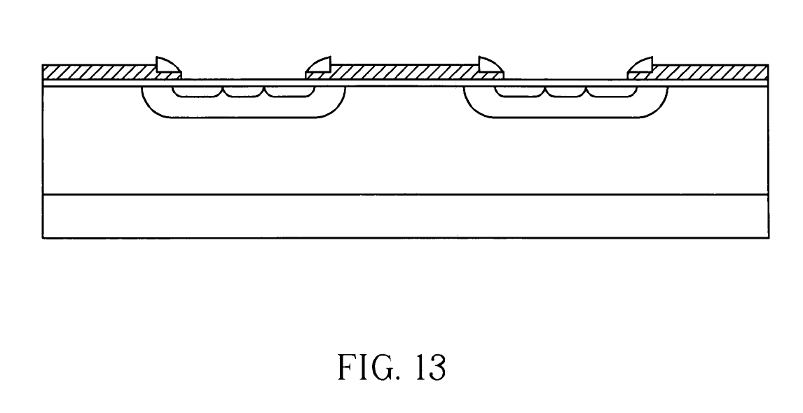

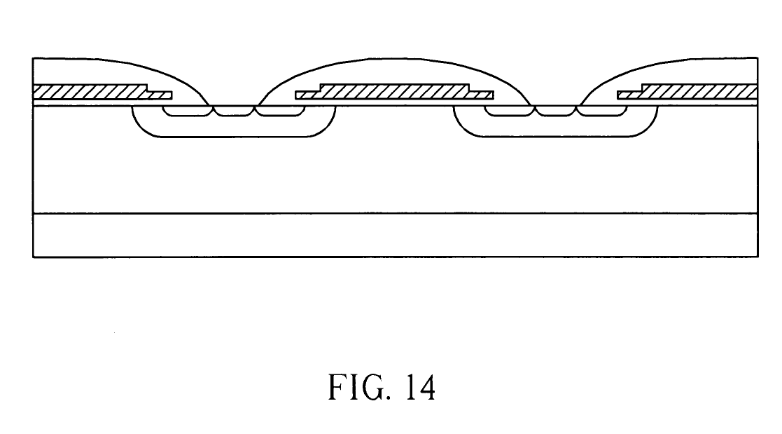

Please refer to FIG. 9 to FIG. 14, which illustrate cross-section diagrams of the MOSFET device 70 during each step in the process 80. FIG. 9 to FIG. 14 respectively correspond to the step 806, 810, 812, 814, 816 and 818. FIG. 14 only shows the status of the MOSFET device 70 after finishing the step 818, and further fabrication steps are known in the prior art and are not given here.

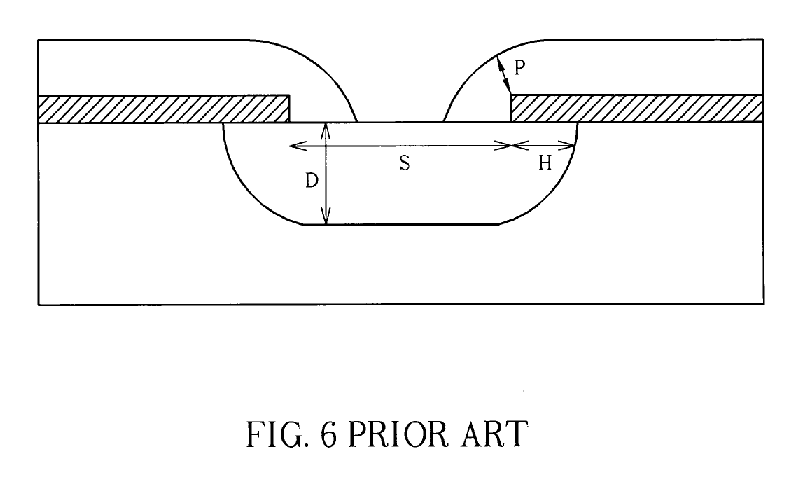

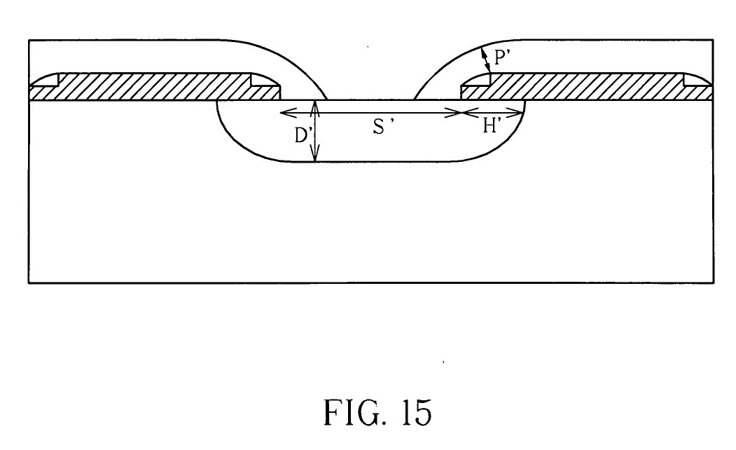

Note that, the MOSFET device 70 fabricated according to the process 80 is a MOSFET device having low Rdson. Please refer to FIG. 15, which illustrates a schematic diagram of channel length of the MOSFET device 70. In FIG. 15, H′ is channel length, D′ is the depth of the well region 708, S′ is the distance between two gate structures, and P′ is the distance of the dielectric layer of the MOSFET device 70 and P′ must keep a fixed distance to isolate source metal and gate 706. Note that, the channel length H′ needs to be fixed for maintaining the same device characteristic of the MOSFET device. Please refer to FIG. 15 and FIG. 6 at the same time. In order to maintain the same device characteristic of the MOSFET device, the channel length H′ shown in FIG. 15 must be identical to the channel length H shown in FIG. 6. The gate structure 706 with gaps in the two sides makes the distance between of the contact window and the gate in the MOSFET device 70 smaller than the distance in the prior art MOSFET device 10.

Or, if the distance between of the contact window and the gate stays the same in the MOSFET device 10 and 70, the upper opening of the contact window of the MOSFET device 70 is larger than that of the MOSFET device 10 because of the gaps on the gate structure 706. As a result, the step coverage of the MOSFET device 70 is better than that of the MOSFET device 10, so that the MOSFET device 70 can use a smaller contact window. From the above, the distance S′ between two gate structures 706 is smaller than the distance S between two gate structures 106. Therefore, the cell of the MOSFET device 70 can be smaller. In a word, the MOSFET device 70 is fabricated according to 2-step etching processes and particularly, the gate structures 706 is formed via the spacer 762 as the mask so that the channel length H′ can be identical to the channel length H even if the depth D′ of the well region 708 is shallower than the depth D of the well region 108. That is, the well region 708 can be a shallow junction well region so as to save time cost for a drive-in process and save production cost.

From the above, the MOSFET device 70 is fabricated according to 2-step etching processes and the gate structure 706 is formed via the spacer 762 as the mask so that the cell of the MOSFET device 70 can be smaller and the well region 708 can be a shallow junction well region. Therefore, Rdson of a parasitic junction field effect transistor of the MOSFET device 70 is minimized so that Rdson of the MOSFET device 70 is minimized. Compared with the MOSFET device 10, the MOSFET device 70 has lower Rdson so that the efficiency of the MOSFET device 70 is enhanced.

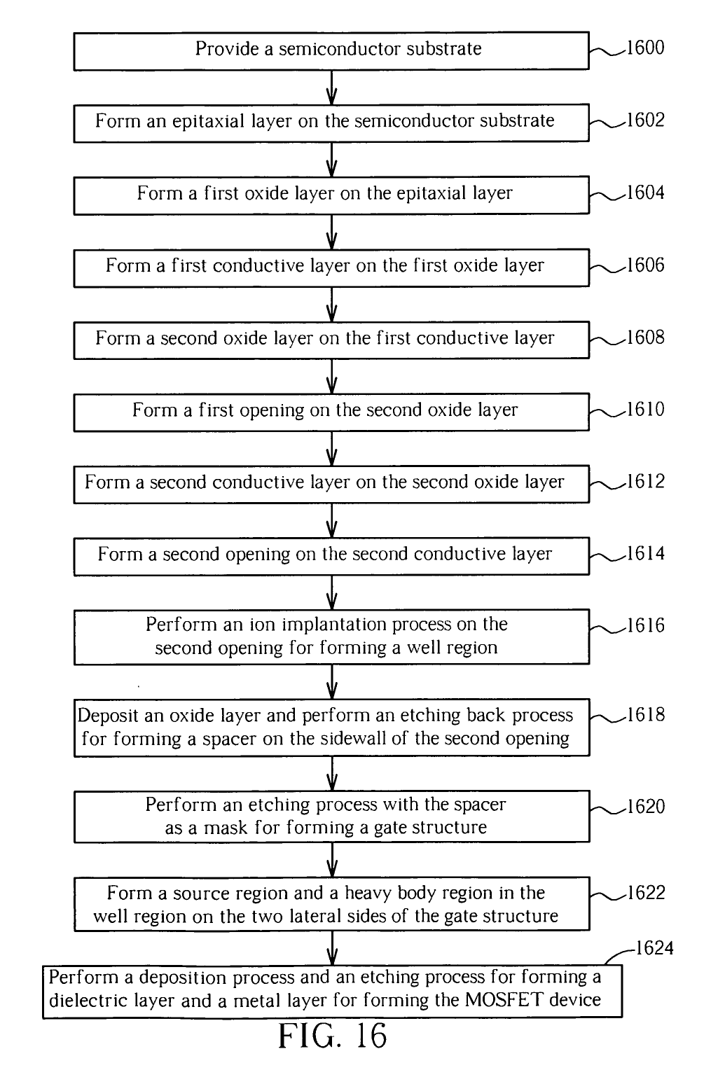

Note that the MOSFET device 70 and the process 80 are embodiments of the present invention, and those skilled in the art can make alterations and modifications accordingly. For example, the present invention further provides a process 160 for improving the problem that it is difficult to control the etching depth of the conductive layer 760 when forming the first opening in the step 808 of the process 80. Please refer to FIG. 16, which illustrates a flowchart of the process 160 for fabricating a MOSFET device 90 according to an embodiment of the present invention. The process 160 comprises the following steps:

Step 1600: Provide a semiconductor substrate.

Step 1602: Form an epitaxial layer on the semiconductor substrate.

Step 1604: Form a first oxide layer on the epitaxial layer.

Step 1606: Form a first conductive layer on the first oxide layer.

Step 1608: Form a second oxide layer on the first conductive layer.

Step 1610: Form a first opening on the second oxide layer.

Step 1612: Form a second conductive layer on the second oxide layer.

Step 1614: Form a second opening on the second conductive layer.

Step 1616: Perform an ion implantation process on the second opening for forming a well region.

Step 1618: Deposit an oxide layer and perform an etching back process for forming a spacer on the sidewall of the second opening.

Step 1620: Perform an etching process with the spacer as a mask for forming a gate structure.

Step 1622: Form a source region and a heavy body region in the well region on the two lateral sides of the gate structure.

Step 1624: Perform a deposition process and an etching process for forming a dielectric layer and a metal layer for forming the MOSFET device.

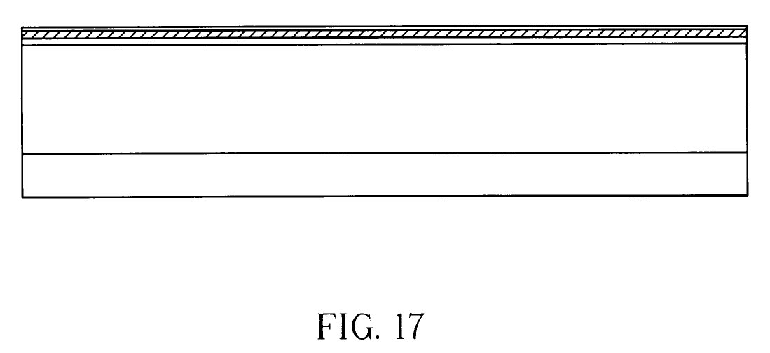

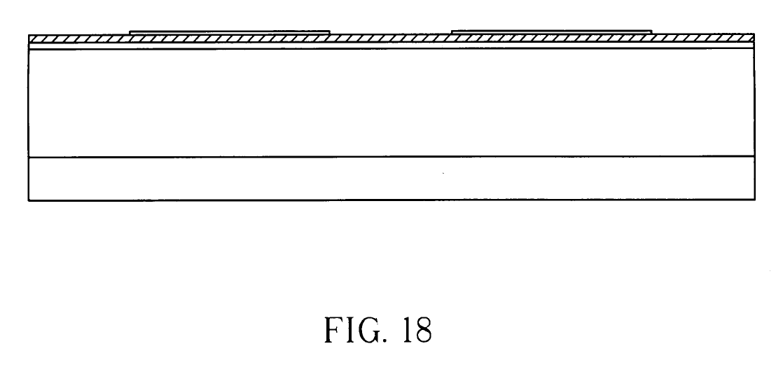

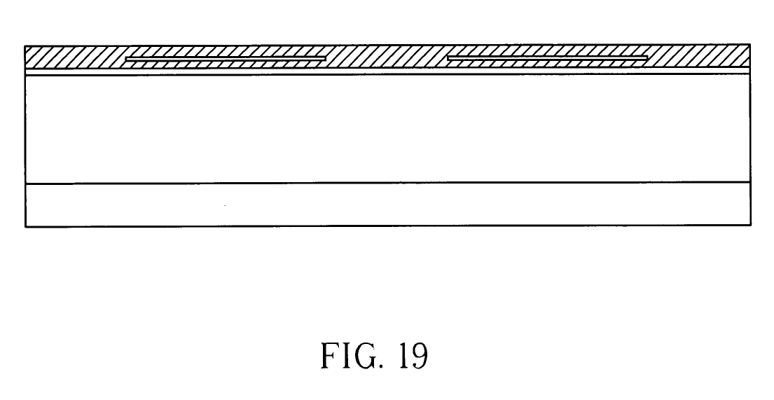

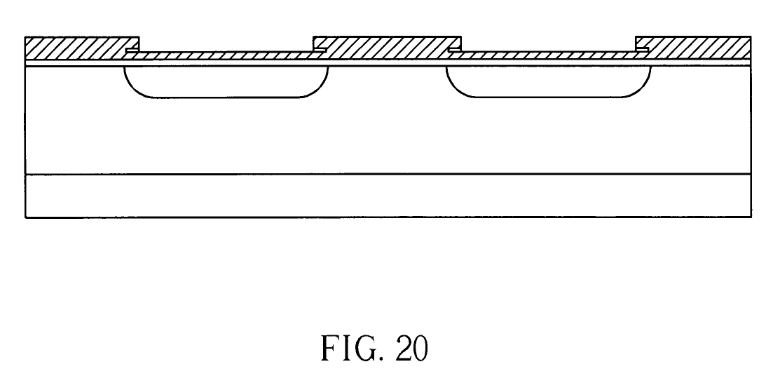

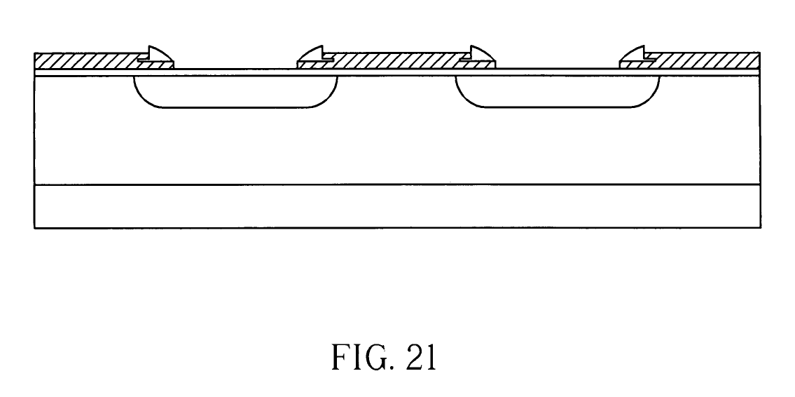

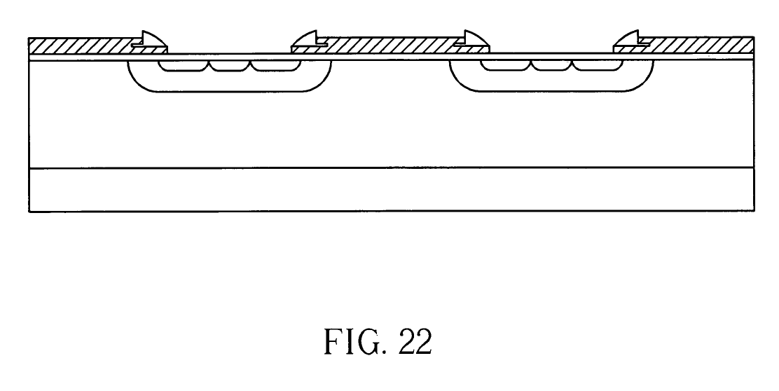

Note that, in the step 1610, forming the first opening on the second oxide layer means etching a portion of the second oxide layer and reserving the remaining second oxide layer for forming the first opening. In the step 1614, forming the second opening on the second conductive layer means etching a portion of the second conductive layer to the top of the remaining second oxide layer and then etching the remaining second oxide layer. Therefore, etching depth is easier to control in the step 1610 to the step 1614 than in the step 808 of the process 80. Those steps after the step 1614 are similar to the process 80. Please refer to FIG. 17 to FIG. 23, which illustrate cross-section diagrams of the MOSFET device 90 during each step in the process 160. FIG. 17 to FIG. 23 respectively corresponds to the step 1608, 1610, 1612, 1616, 1620, 1622 and 1624, those skilled in the art shall realize each step according to the figures and the details are not given here.

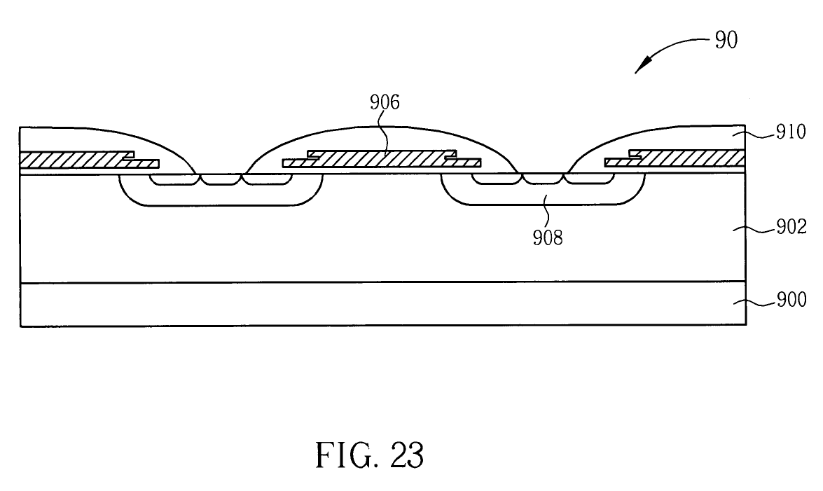

The cross-section diagram of the MOSFET device 90 is shown in FIG. 23. The MOSFET device 90 comprises a semiconductor substrate 900, an epitaxial layer 902, a gate structure 906, a well region 708 and a dielectric layer 910. The semiconductor substrate 900 is a silicon substrate. The epitaxial layer 902 is formed on the semiconductor substrate 900. The gate structure 906 is formed according to the step 1606 to 1620 of the process 160. The well region 908 is formed on the two lateral sides of the gate structure 906 and comprises a source region and a heavy body region. The dielectric layer 910 is formed on the gate structure 906. In addition, a metal layer is formed on the dielectric layer 910 and is not shown in FIG. 23. Similar to the MOSFET device 70, the MOSFET device 90 is fabricated according to 2-step etching processes and the gate structure 906 is formed via the spacer as a mask so that the cell of the MOSFET device 90 can be smaller and the well region 908 can be a shallow junction well region. As a result, the MOSFET device 70 has low Rdson.

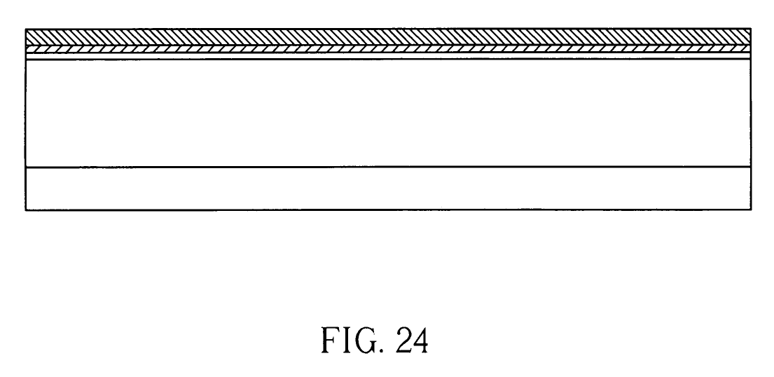

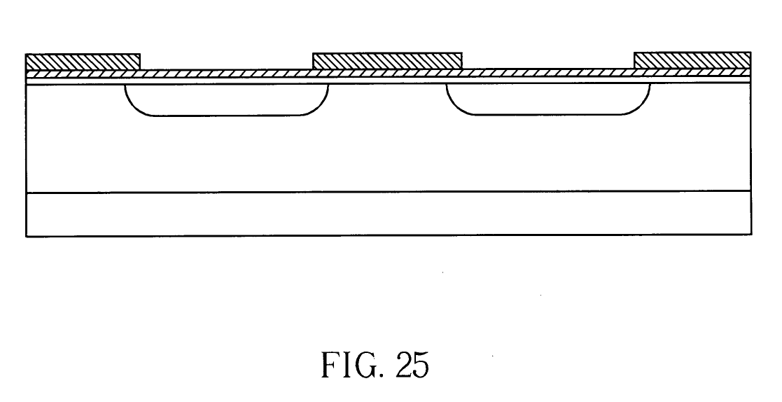

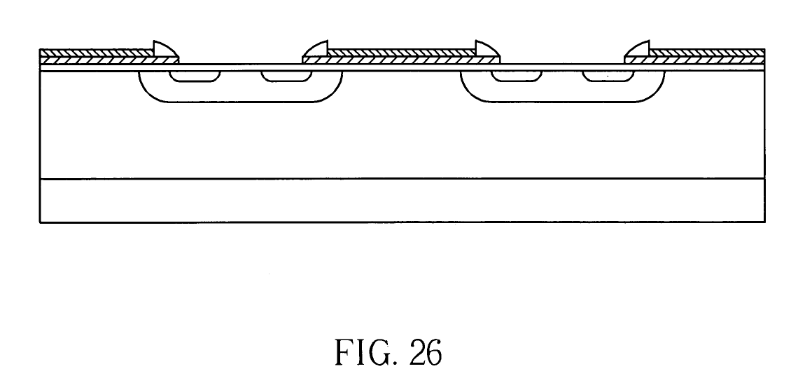

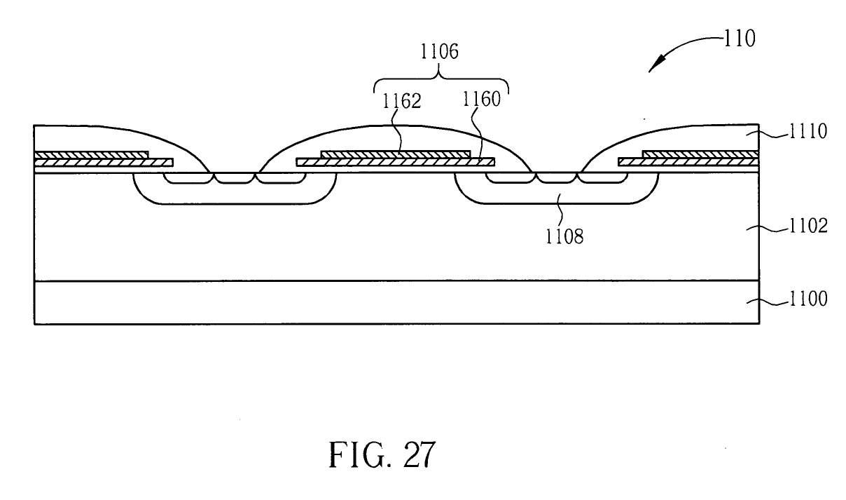

On the other hand, in the present invention, the material of the oxide layer and the conductive layer and an order of corresponding fabrication steps such as a deposition process or an etching process can be modified according to requirements. Please refer to FIG. 24 to FIG. 27, which illustrate cross-section diagrams of a MOSFET device 110 during each step in a corresponding process according to an embodiment of the present invention. The cross-section diagram of the MOSFET device 110 is shown in FIG. 27. The MOSFET device 110 comprises a semiconductor substrate 1100, an epitaxial layer 1102, a gate structure 1106, a well region 1108 and a dielectric layer 1110. The semiconductor substrate 1100 is a silicon substrate. The epitaxial layer 1102 is formed on the semiconductor substrate 1100. The gate structure 1106 is formed by dielectric layers 1160 and 1162 with different material according to 2-step etching processes. The well region 1108 is formed on the two lateral sides of the gate structure 1106 and comprises a source region and a heavy body region. The dielectric layer 1110 is formed on the gate structure 1106. In addition, a metal layer is formed on the dielectric layer 1110 and is not shown in FIG. 27. In the MOSFET device 70 and 90, the dielectric layer is made of polysilicon. In the MOSFET device 110, the dielectric layer 1162 on the gate structure 1106 is made of tungsten silicide (WSi). Those skilled in the art shall realize each step according to the figures and the details are not given here. Similar to the MOSFET device 70 and 90, the MOSFET device 110 has low Rdson.

In conclusion, the MOSFET device of the present invention is fabricated according to 2-step etching processes and the gate structure of the MOSFET device is formed via the spacer as the mask, so that the cell of the MOSFET device can be smaller and the well region can be a shallow junction well region. As a result, the MOSFET device of the present invention has low Rdson so that the efficiency of the MOSFET device is enhanced.

Those skilled in the art will readily observe that numerous modifications and alterations of the device and method may be made while retaining the teachings of the invention.

What is claimed is:

1. A metal-oxide-semiconductor (MOS) transistor device comprising:
a semiconductor substrate;
an epitaxial layer formed on the semiconductor substrate;
an oxide layer formed on the epitaxial layer;
a gate structure formed on the oxide layer comprising:
a conductive layer having a gap on the top of the sidewall of the conductive layer; and
a spacer formed on the gap; and
a shallow junction well region formed on the two lateral sides of the gate structure comprising a source region and a heavy body region.

2. The MOS transistor device of claim 1, wherein the conductive layer is formed according to a first etching process and a second etching process.

3. The MOS transistor device of claim 2, wherein the first etching process is utilized for etching a portion of the conductive layer for forming a first opening.

4. The MOS transistor device of claim 3, wherein the first opening is utilized for an ion implantation process for forming the shallow junction well region.

5. The MOS transistor device of claim 2, wherein the second etching process comprises using the spacer as a mask to etch the conductive layer to the top of the oxide layer for forming a second opening.

6. The MOS transistor device of claim 5, wherein the second opening is utilized for an ion implantation process for forming the source region and the heavy body region.

7. The MOS transistor device of claim 1, wherein the spacer is formed according to an etching back process.

8. The MOS transistor device of claim 1, wherein the semiconductor substrate is a silicon substrate.

9. The MOS transistor device of claim 1, wherein the oxide layer is made of silicon oxide.

10. The MOS transistor device of claim 1, wherein the conductive layer is made of polysilicon.

11. The MOS transistor device of claim 1 is a vertical double diffused metal-oxide-semiconductor (VDMOS) transistor device.

12. A method for fabricating a metal-oxide-semiconductor (MOS) transistor device comprising:
providing a semiconductor substrate;
forming an epitaxial layer on the semiconductor substrate;
forming an oxide layer on the epitaxial layer;
forming a conductive layer on the oxide layer;
forming a first opening on the conductive layer;
performing a first ion implantation process on the first opening for forming a shallow junction well region;
depositing an oxide layer and performing an etching back process for forming a spacer on the sidewall of the first opening;
performing an etching process with the spacer as a mask for forming a gate structure;
forming a source region and a heavy body region in the shallow junction well region on the two lateral sides of the gate structure; and
performing a depositing process and an etching process for forming a dielectric layer and a metal layer for forming the MOS transistor device.

13. The method of claim 12, wherein forming the first opening on the conductive layer comprises etching a portion of the conductive layer for forming the first opening.

14. The method of claim 12, wherein the etching process is utilized for etching the conductive layer to the top of the oxide layer for forming a second opening.

15. The method of claim 14, wherein the second opening is utilized for performing a second ion implantation process for forming the source region and the heavy body region.

16. The method of claim 12, wherein the semiconductor substrate is a silicon substrate.

17. The method of claim 12, wherein the oxide layer is made of silicon oxide.

18. The method of claim 12, wherein the conductive layer is made of polysilicon.

19. The method of claim 12, wherein the MOS transistor device is a vertical double diffused metal-oxide-semiconductor (VDMOS) transistor device.
